(19) United States
(12) Patent Application Publication
(10) Pub. No.: US 2025/0081660 A1
(43) Pub. Date: Mar. 6, 2025

(54) DEVICE AND METHOD FOR HOLDING A PHOTOVOLTAIC CELL, DEVICE FOR DEPOSITING THIN FILMS AND METHOD FOR PASSIVATING A PHOTOVOLTAIC CELL

(71) Applicant: COMMISSARIAT A L'ENERGIE ATOMIQUE ET AUX ENERGIES ALTERNATIVES, PARIS (FR)

(72) Inventors: Benoît MARTEL, GRENOBLE CEDEX 09 (FR); Mickaël ALBARIC, GRENOBLE CEDEX 09 (FR); Samuel HARRISON, GRENOBLE CEDEX 09 (FR)

(21) Appl. No.: 18/824,387

(22) Filed: Sep. 4, 2024

(30) Foreign Application Priority Data
Sep. 5, 2023 (FR) 2309299

(51) Int. Cl. H01L 31/18; C23C 8/06

(52) U.S. Cl. CPC H10F 71/129; C23C 8/06

(57) ABSTRACT

A device for holding a photovoltaic cell to form a passivation layer on the photovoltaic cell, the photovoltaic cell including a first face, a second face and a peripheral edge connecting the first face and the second face, the device including a first support part including a first support face and a second support face, the first support face being provided with a first seal shaped according to a perimeter of the photovoltaic cell, a second support part including a third support face and a fourth support face, the third support face being provided with a second seal shaped according to the perimeter of the photovoltaic cell, and a compression device configured to hold the photovoltaic cell bearing tightly against the first seal and against the second seal.

### CROSS-REFERENCE TO RELATED APPLICATIONS

This application claims priority to French Patent Application No. 2309299, filed Sep. 5, 2023, the entire content of which is incorporated herein by reference in its entirety.

### FIELD

This invention generally relates to the manufacture of photovoltaic cells.

The invention more particularly relates to a device and a method for holding at least one photovoltaic cell.

It also relates to a thin film deposition device and a method for passivating at least one photovoltaic cell.

### BACKGROUND

A photovoltaic module comprises a multitude of identical photovoltaic cells connected in series and/or parallel to output the voltage and/or current required to power electric devices. The most common module format employs 60 square (or “pseudo-square”) cells, 156 mm on a side, distributed into six strings of ten cells connected in series. The six strings of photovoltaic cells are also connected in series. The open-circuit voltage across the module is then equal to 60 times the threshold voltage of a photovoltaic cell. The electric current of the module corresponds approximately to the current provided by each photovoltaic cell (in practice, the photovoltaic cells do not have exactly the same performance and the electric current is limited by the least efficient cell in the module).

With the latest photovoltaic cell technologies, especially PERT (Passivated Emitter and Rear Totally diffused) technology, the current of a 156 mm×156 mm monofacial cell reaches high values, in the order of 9 A for solar irradiance of 1000 W/m². These current values are increased by around 20% when a bifacial cell is used, due to the diffuse solar radiation captured on the rear face of the cell. This high electric current circulates in the interconnection elements between the cells in the module, and causes significant resistive losses.

In order to reduce these resistive losses, one solution is to assemble modules with photovoltaic cells with a smaller surface area, and therefore lower current. These cells with a smaller surface area are commonly called “sub-cells” and are obtained by cutting full-size photovoltaic cells (for example, 156 mm×156 mm).

However, cutting a photovoltaic cell creates new edges that are bare. In addition, cutting (with a laser, for example) is likely to create defects and insert impurities in proximity to the cutting plane. These defects and impurities decrease the lifetime of the free charge carriers by acting as recombination centres for electron-hole pairs, resulting in a reduction in cell efficiency. This phenomenon is particularly pronounced for heterojunction (HET) photovoltaic cells, which by nature have very few surface defects and where the creation of a few localised defects is enough to significantly reduce the cell's electrical performance.

It is especially known from document FR3091025 that a method for passivating photovoltaic cells makes it possible to localise the deposition of a passivation material in the vicinity of one edge of the photovoltaic cell only.

To be compatible with the requirements of industrial production, while depositing a passivation material only onto the edges of the photovoltaic cells, document FR3091025 describes an arrangement consisting in stacking a plurality of photovoltaic cells on one another, the stack resting directly on a support.

According to this arrangement, the front and rear faces of each photovoltaic cell are in direct contact with one of the faces of another photovoltaic cell or with the support. This direct contact results in risks of degrading these front and rear faces. The front and/or rear faces comprise metallisations (for example, collection fingers, busbars) to which interconnection elements (stripes, wires, etc.) are welded or bonded.

In addition, stacking a large number of photovoltaic cells also involves risks of breakage of the photovoltaic cells included in the stack, in particular for photovoltaic cells positioned in a lower part of the stack and which are then subjected to the pressure exerted by all the photovoltaic cells stacked above them.

Furthermore, in practice, the stacking of photovoltaic cells directly on one another does not allow the deposition of the thin film to be confined to the peripheral edge of the photovoltaic cell. Part of the thin film is deposited onto the front and rear faces of the photovoltaic cell.

### SUMMARY

An aspect of the present invention is therefore to improve manufacture of photovoltaic cells, especially by ensuring that the process for passivating the photovoltaic cells does not degrade the photovoltaic cells themselves or their electrical performance.

An aspect of the invention then relates firstly to a device for holding at least one photovoltaic cell in order to form a passivation layer on a part of said photovoltaic cell, the photovoltaic cell comprising a first face, a second face, opposite to said first face, and a peripheral edge connecting the first face and the second face, the holding device comprising:
a first support part comprising a first support face and a second support face opposite to said first support face, the first support face being provided with a first seal shaped according to a perimeter of the photovoltaic cell,
a second support part comprising a third support face and a fourth support face opposite to said third support face, the third support face being provided with a second seal shaped according to the perimeter of the photovoltaic cell, and
a compression device configured to hold the photovoltaic cell bearing tightly against the first seal and against the second seal.

Thus, beneficially according to an embodiment of the invention, when the photovoltaic cell is held in the holding device, only the peripheral edge of the photovoltaic cell is visible and accessible from the outside of the holding device (into which the photovoltaic cell is inserted). In other words, the first seal and the second seal isolate the first face and the second face of the photovoltaic cell, placed in the holding device, from the outside of the holding device.

Thus, when depositing a passivation layer, only the peripheral edge of the photovoltaic cell is exposed to the passivation species, so that the passivation layer is formed only on this peripheral edge.

Furthermore, by virtue of the presence of the seals, the first and second faces of the photovoltaic cell are not subjected to stresses at the zones provided with metallisations. Their electrical performance is therefore preserved.

Further to the characteristics just discussed in the previous paragraphs, the holding device according to one aspect of the invention may have one or more additional characteristics from among the following, considered individually or according to any technically possible combinations:
a positioning system is provided for positioning the photovoltaic cell between the first support part and the second support part;
the positioning system comprises guide elements positioned at the border of the first seal and/or the second seal so as to position the perimeter of the photovoltaic cell facing the first seal and the second seal;
the positioning system comprises at least one robotic arm configured to position the photovoltaic cell between the first support part and the second support part so that the perimeter of the photovoltaic cell is positioned facing the first seal and the second seal;
the first support face of the first support part comprises a groove shaped to attach the first seal to the first support part;
the third support face of the second support part comprises a groove shaped to attach the second seal to the second support part;
the compression device is configured to exert a pressure force greater than 2 Newtons to hold the photovoltaic cell bearing tightly against the first seal and against the second seal;
the compression device is configured to exert a pressure force of between 2 and 10 Newtons to hold the photovoltaic cell bearing tightly against the first seal and against the second seal;
the compression device comprises two pistons positioned on either side of the first support part and the second support part;
the compression device comprises a load element positioned on the second support part so as to exert said pressure force;
the first seal and the second seal are formed from a flexible polymer material;
there are also provided:
   a third support part comprising a fifth support face and a sixth support face opposite to said fifth support face, the fifth support face being provided with a third seal shaped according to another perimeter of another photovoltaic cell, said other perimeter of the other photovoltaic cell being similar to the perimeter of the photovoltaic cell, said other photovoltaic cell comprising another first face, another second face, opposite to said other first face, and another peripheral edge connecting the other first face and the other second face,
   the fourth support face of the second support part being provided with a fourth seal shaped according to the perimeter of the other photovoltaic cell,
   the compression device being configured to hold the other photovoltaic cell bearing tightly against the third seal and against the fourth seal.

An aspect of the invention also relates to a device for depositing thin films (and especially for depositing at least one passivation layer) onto at least part of a photovoltaic cell comprising:
a holding device as previously defined,
at least one photovoltaic cell positioned in the holding device,
an enclosure for depositing thin films (and especially for depositing at least one passivation layer) comprising a side wall delimiting a housing for accommodating the holding device in which said photovoltaic cell is positioned, and
an injector for injecting at least one passivation species enabling a passivation layer to be formed on the peripheral edge of the photovoltaic cell when the passivation species is flush with the peripheral edge of the photovoltaic cell.

A pumping device is also provided for pumping the passivation species, which are configured to enable circulation of the passivation species around the holding device along a directional flow.

An aspect of the present invention also relates to a method for holding at least one photovoltaic cell comprising a first face, a second face, opposite to said first face, and a peripheral edge connecting the first face and the second face, the method comprising steps of:
providing a first support part comprising a first support face and a second support face opposite to said first support face, the first support face being provided with a first seal shaped according to a perimeter of the photovoltaic cell,
providing a second support part comprising a third support face and a fourth support face opposite to said third support face, the third support face being provided with a second seal shaped according to the perimeter of the photovoltaic cell,
positioning the photovoltaic cell between the first support part and the second support part, and
compressing a stack formed by the first support part, the photovoltaic cell and the second support part so as to hold the photovoltaic cell bearing tightly against the first seal and against the second seal.

In this holding method, the positioning step comprises successively positioning the first support part, the photovoltaic cell and the second support part.

Finally, an aspect of the invention relates to a method for passivating at least one photovoltaic cell comprising the steps of:
holding the photovoltaic cell in a holding device according to a holding method as previously introduced,
positioning the holding device provided with the photovoltaic cell in a thin film deposition enclosure, and
injecting at least one passivation species into the thin film deposition enclosure so as to form a passivation layer on a peripheral edge of the photovoltaic cell when the passivation species is flush with the peripheral edge of the photovoltaic cell.

### BRIEF DESCRIPTION OF THE FIGURES

Other characteristics and benefits of the invention will be appear clearly from the description given below, by way of indicating and in no way limiting purposes, with reference to the appended figures, among which:

FIG. 1 is a perspective representation of a holding device according to a first embodiment of the invention,

FIG. 2 is a cross-section view along axis A-A of the holding device shown in FIG. 1,

FIG. 3 is a cross-section view of an alternative to the holding device of FIG. 1,

FIG. 4 is a top view of a support part comprised in the holding device of FIG. 1,

FIG. 5 represents a side view of a holding device, in a loading position, according to a second embodiment in accordance with the invention,

FIG. 6 represents a side view of a holding device, in a compression position, according to the second embodiment in accordance with the invention,

FIG. 7 represents a side view of a holding device, in a loading position, according to a third embodiment in accordance with the invention,

FIG. 8 represents a side view of a holding device, in a compression position, according to a third embodiment in accordance with the invention,

FIG. 9 represents a side view of a holding device, in a loading position, according to a fourth embodiment in accordance with the invention,

FIG. 10 represents a side view of a holding device, in a compression position, according to a fourth embodiment in accordance with the invention,

FIG. 11 is a top view of a support part comprised in the holding device of FIG. 9, and

FIG. 12 represents an example of the thin film deposition device in accordance with the present invention.

For the purpose of clarity, identical or similar elements are identified by identical reference signs throughout the figures.

### DETAILED DESCRIPTION OF AT LEAST ONE EMBODIMENT

An aspect of the present invention is to improve manufacture of photovoltaic cells and in particular to improve the passivation phase of photovoltaic cells. More particularly, an aspect of the present invention is initially to improve holding of photovoltaic cells during the passivation phase.

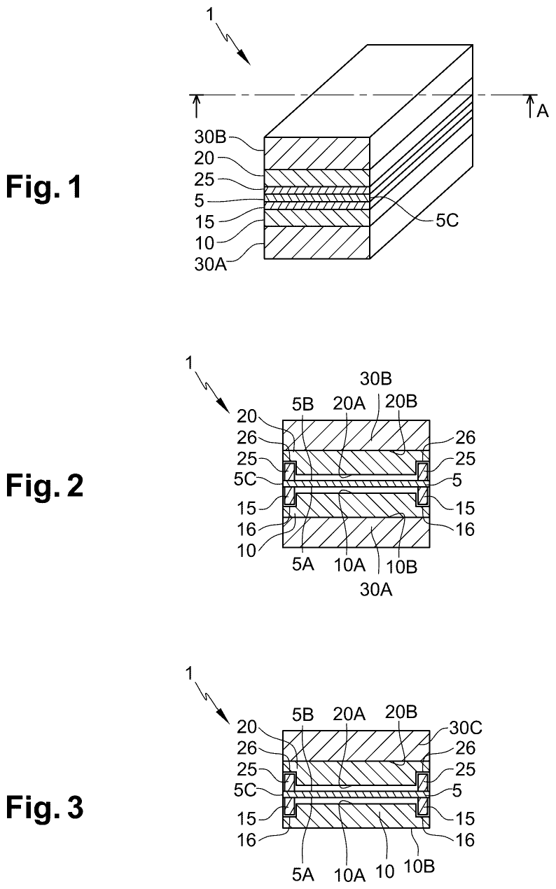

For this purpose, one or more aspects of the invention provides, as shown in FIGS. 1 to 11, a device 1; 100; 150; 200 for holding at least one photovoltaic cell 5. This holding device 1; 100; 150; 200 corresponds in fact here to a cradle for loading at least one photovoltaic cell 5. The term “cradle” here means a support receiving the photovoltaic cell 5, onto the surface of which a thin film deposition of a passivation layer will be made.

It is to be noted here that the photovoltaic cell 5 is not part of the holding device 1; 100; 150; 200 per se. However, for the purpose of clarity, the holding device 1; 100; 150; 200 is described in relation to this photovoltaic cell 5.

The photovoltaic cells 5 concerned by the present invention are, for example, sub-cells, that is, portions or pieces of a full-size photovoltaic cell (also referred to as a “whole” photovoltaic cell).

The sub-cells are obtained, for example, by cutting full-size photovoltaic cells.

The full-size photovoltaic cells have been first manufactured from semiconductor substrates, for example crystalline silicon. These substrates have been initially cut from a silicon ingot and then subjected to several manufacturing steps (for example, surface structuring, doping, annealing, passivation, screen printing, etc. steps), but no further cutting steps. Full-size photovoltaic cells have passivation layers on all their faces and side surfaces.

The photovoltaic cells 5 concerned by the present invention each comprise a first face 5A and a second face 5B, opposite to the first face 5A. The first face 5A is, for example, that intended to be exposed to incident solar radiation.

Each photovoltaic cell 5 also comprises a peripheral edge 5C connecting the first face 5A and the second face 5B. This peripheral edge 5C therefore corresponds to the side surface connecting the first face 5A and the second face 5B. By definition here, the peripheral edge 5C therefore extends over the entire perimeter of the first face 5A and the second face 5B of the photovoltaic cell 5. In this description, by “perimeter” of the photovoltaic cell 5, it is meant the contour line of the first face 5A and/or the second face 5B.

Viewed from the front (from the first face 5A or the second face 5B), the photovoltaic cells 5 have, in an embodiment, a rectangular or pseudo-rectangular shape. In the pseudo-rectangular format, the four corners of the photovoltaic cells 5 are truncated or rounded. In particular, the photovoltaic cells 5 can have a square or pseudo-square shape.

The perimeter of the photovoltaic cell 5 therefore has here a rectangular or pseudo-rectangular shape (or, in the particular case, a square or pseudo-square shape).

The dimensions of the first face 5A and the second face 5B are generally standardised, for example 156 mm×156 mm.

Photovoltaic cells 5 can be monofacial or bifacial cells. In the case of a monofacial cell, only the first face 5A of the photovoltaic cell 5 captures solar radiation. In the case of a bifacial cell, both faces 5A, 5B of the photovoltaic cell 5 capture the solar radiation. The first face 5A is then that enabling the maximum electric current to be obtained when facing the sun.

In an embodiment, the photovoltaic cells 5 are ready to be interconnected into a string of cells. They are provided on the first face 5A and/or on the second face 5B with one or more metallisations (not represented) intended to collect the photogenerated charge carriers and to receive interconnection elements, for example metal wires or stripes. The metallisations are in an embodiment electrically conductor tracks called “busbars”. The busbars can electrically connect collection fingers distributed over the entire surface area of the first face 5A and/or the second face 5B. The second face 5B of the photovoltaic cells 5 can also be entirely metallised. In an alternative implementation, the photovoltaic cells 5 are devoid of busbars 5 but include only collection fingers.

As the photovoltaic cells 5 are obtained by cutting a full-size photovoltaic cell, the faces of which are provided with passivation layers, the first face 5A and the second face 5B of each photovoltaic cell 5 have a passivation layer. This passivation layer renders the surface defects of the photovoltaic cell 100 inactive and improves the lifetime of the photogenerated charge carriers.

In contrast, the peripheral edge 5C of the photovoltaic cell comprises zones where the semiconductor material (that is, silicon) has been bared. In other words, these zones of the peripheral edge 5C are devoid of a passivation layer (because of cutting), unlike the first face 5A, the second face 5B and the (possible) other zones of the peripheral edge 5C of the photovoltaic cell 5. For example, when a full-size photovoltaic cell is cut into four parallel cell strips, two cell strips have two non-passivated parallel edges, and two other cell strips have a single non-passivated edge.

An aspect of the present invention is therefore to protect, by forming a passivation layer, these zones in which the semiconductor material is bared, without this deposit reaching the first face 5A and the second face 5B (as this would risk degrading the electrical performance of the photovoltaic cell 5).

For this, an aspect of the present invention firstly relates to the device 1; 100; 150; 200 for holding the photovoltaic cell 5 with a view to forming a passivation layer on a part of this photovoltaic cell 5.

FIGS. 1 to 11 represent different embodiments of the holding device according to this invention.

FIGS. 1 to 4 represent a first embodiment of the holding device 1. As is visible in these figures, the holding device 1 comprises a first support part 10, a second support part 20 and compression devices 30A, 30B; 30C.

The first support part 10 comprises a first support face 10A and a second support face 10B opposite to the first support face 10A. It is formed from a so-called solid material, that is, one that does not include any empty portions. This makes it possible, in particular, to reinforce the strength of the first support part 10, in particular during the compression implemented by the compression devices 30A, 30B, 30C (as will be described later). The solid material is, for example, a stainless steel or anodised aluminium type material. This material used is particularly adapted to the implementation of the passivation of photovoltaic cells because it will not be damaged during this implementation.

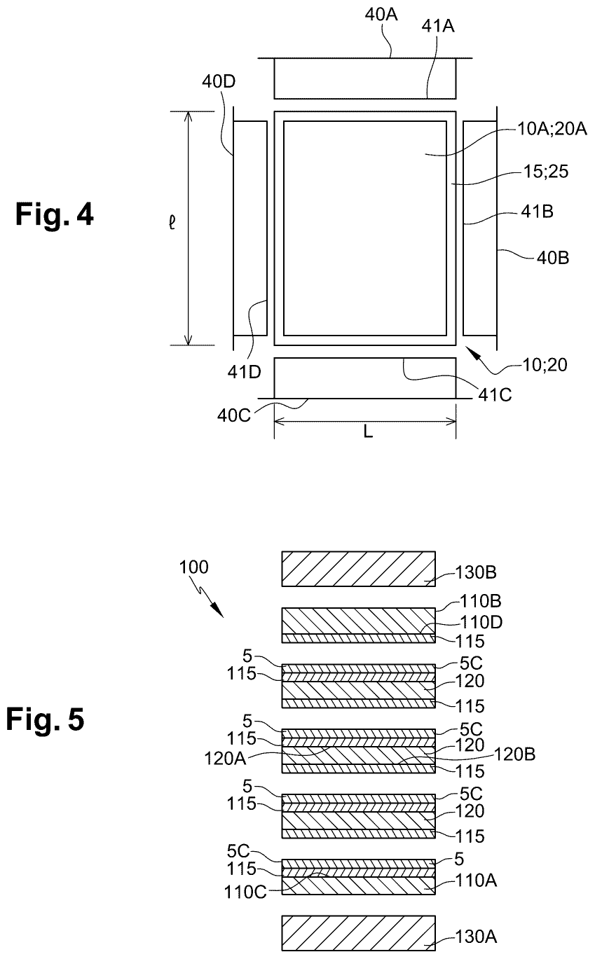

As is visible in FIGS. 1 and 4, the first support part 10, in an embodiment, has an overall parallelepipedal shape. Alternatively, it could have a different shape, as long as the shape concerned has two substantially parallel opposite faces (whatever their shape).

The first support part 10 here includes a length l and a width L (FIG. 4), corresponding to characteristic dimensions of the rectangular cross-section of the first support part 10 (parallelepipedal shape). The length l and width L are determined here as a function of the dimensions of the photovoltaic cell 5.

In an embodiment, the length l and width L of the first support part 10 are similar to the length and width of the photovoltaic cell 5. By “similar”, it is meant in this description that the difference between the two quantities considered is less than 10%.

The length l is, for example, greater than 30 millimetres (mm). In an embodiment, it is between 50 and 210 mm.

The width L is, for example, greater than 20 mm. In an embodiment, it is

between 25 and 210 mm.

As represented in FIGS. 1 to 4, the first support face 10A is provided with a first seal 15. The first seal 15 is configured to bear against the first face 5A of the photovoltaic cell 5.

The first seal 15 has here a rectangular transverse cross-section (FIGS. 2 and 3). Alternatively, its transverse cross-section may, for example, be cylindrical.

Beneficially here, the first seal 15 is shaped according to the perimeter of the photovoltaic cell 5. In other words, the first seal 15 is in the form of a cord having the shape of the circumference (that is, the outer limit) of the photovoltaic cell 5.

Here, given that the photovoltaic cell 5 has a rectangular shape, the first seal 15 therefore extends according to a rectangular shape corresponding to the periphery of the photovoltaic cell 5 (as visible in FIG. 4).

In practice, the first seal 15 is formed from a flexible polymer material. Such a flexible polymer material is defined, for example, on the basis of the standard Shore A hardness scale. Within the scope of the invention, the materials considered have, for example, an index of between 70 and 90 on this Shore A scale. For example, they are fluoroelastomers here.

In particular, the flexible polymer material used for the first seal 15 is adapted to withstand passivation temperatures of between 50 and 200 degrees Celsius (° C.).

For example, they are materials such as fluorinated elastomers (of the FKM type) or a mixture of synthetic rubber, elastomer and a fluorinated polymer material.

These materials are particularly beneficial for forming the first seal because they have qualities of resistance to high temperatures (typically up to 200° C.) and to gases such as ozone and oxygen or plasma.

Furthermore, these materials have a low permeability to gases, especially those used for the passivation of the photovoltaic cell described hereafter.

In other words, the materials used to form the first seal 15 are particularly adapted to the implementation of the passivation of photovoltaic cells because they will not be damaged during this implementation. By virtue of the properties of the material used to form it, the sealing qualities of the first seal 15 are preserved for the applications aimed at in the present invention (and in particular for the deposition of passivation layers).

The first seal 15 is, for example, a Viton™ brand fluoroelastomer static seal.

The first seal 15 is attached to the first support face 10A of the first support part 10. Whatever the attachment used, the first seal 15 is attached to the first support part 10 so as to be located facing the periphery of the photovoltaic cell 5. More particularly, the first seal 15 is attached to the first support part 10 so as to be located facing the end border of the first face 5A of the photovoltaic cell 5.

Beneficially, the first support face 10A of the first support part 10 comprises a groove 16 shaped to enable the first seal 15 to be attached in the first support part 10.

As is visible in FIGS. 2 and 3, the groove 16 is “dug” into the first support part 10 from the first support face 10A of the first support part 10.

Here, the groove 16 extends at the border of the first support part 10, over the entire periphery of the first support face 10A. This enables the first seal 15 to be positioned (and attached) facing the periphery of the first face 5A of the photovoltaic cell 5.

To enable the first seal 15 to be attached to the first support part 10, the groove 16 has, for example, a smaller cross-sectional area (in the plane of the first support face 10A) at its opening (therefore, at the first support face 10A) than at its bottom wall (in a plane parallel to the plane of the first support face 10A).

The first seal 15 is inserted into the groove 16 thus shaped by exerting a pressure force (that is, compressing it). The opening of the groove, which has a smaller cross-sectional area, then makes it possible to hold the first seal 15 in the groove 16, and thus to attach it to the first support part 10.

Alternatively, the groove 16 may have a smaller transverse cross-sectional area (that is, in a plane orthogonal to the first support face 10A) than the transverse cross-sectional area of the first seal 15.

The first seal 15 is inserted into the groove 16 shaped according to this alternative by exerting a pressure force (that is, compressing it). Once inserted into this groove 16, the first seal 15 relaxes. This relaxation then results in a pressure force being exerted, by the first seal 15, on the walls of the groove 16. This then holds the first seal 15 in the groove 16 (and therefore enables it to be attached to the first support part 10).

As an alternative to the groove described, the first seal can be attached by bonding to the first support face 10A of the first support part 10. The glue used for bonding especially has properties of resistance to high temperatures (typically up to 200° C.). The glue also has low permeability to gases, especially to the gases used for passivation of the photovoltaic cell described hereafter. A fluoroelastomer-based glue can, for example, be used in this alternative.

As represented in FIGS. 1 to 4, the holding device 1 also comprises the second support part 20. This second support part 20 has characteristics similar to those of the first support part 10 detailed previously. In this first embodiment of the invention, the second support part 20 can be seen as symmetrical to the first support part 10 relative to a plane in which the photovoltaic cell 5 is positioned. These characteristics are set forth hereinafter within the context of the second support part 20.

The second support part 20 comprises a third support face 20A and a fourth support face 20B opposite to the third support face 20A. It is formed from a so-called solid material, that is, one that does not include any empty portions. In particular, this makes it possible to reinforce the strength of the second support part 20, in particular during compression implemented by the compression device (as will be described hereinafter). The solid material is, for example, a stainless steel or anodised aluminium type material. This material is particularly adapted to the implementation of the passivation of photovoltaic cells, as it will not be damaged during this implementation.

As is visible in FIGS. 1 and 4, the second support part 20, in an embodiment, has an overall parallelepipedal shape. Alternatively, it could have a different shape, as long as the shape considered has two substantially parallel opposite faces (regardless of their shape).

The second support part 20 here includes a length l and a width L (FIG. 4), corresponding to characteristic dimensions of the rectangular section of the second support part 20 (parallelepipedal shape). The length l and width L are determined here as a function of the dimensions of the photovoltaic cell 5.

In an embodiment, the length l and width L of the second support part 10 are similar to the length and width of the photovoltaic cell 5.

The length l is, for example, greater than 30 millimetres (mm). In an embodiment, it is between 50 and 210 mm.

The width L is, for example, greater than 20 mm. In an embodiment, it is between 25 and 210 mm.

As represented in FIGS. 1 to 4, the third support face 20A is provided with a second seal 25. The second seal 25 is configured to bear against the second face 5B of the photovoltaic cell 5.

The second seal 25 has a rectangular transverse cross-section (FIGS. 2 and 3). Alternatively, its transverse cross-section may, for example, be cylindrical.

Beneficially here, the second seal 25 is shaped according to the perimeter of the photovoltaic cell 5. In other words, the second seal 25 is in the form of a cord having the shape of the circumference (that is, the outer limit) of the photovoltaic cell 5.

Here, given that the photovoltaic cell 5 has a rectangular shape, the second seal 25 therefore extends according to a rectangular shape corresponding to the periphery of the photovoltaic cell 5 (as visible in FIG. 4).

In practice, the second seal 25 is formed from a flexible polymer material. Such a flexible polymer material is defined, for example, on the basis of the standard Shore A hardness scale. Within the scope of the invention, the materials considered have, for example, an index of between 70 and 90 on this Shore A scale. For example, they are fluoroelastomers here.

In particular, the flexible polymer material used for the second seal 25 is adapted to withstand passivation temperatures of between 50 and 200 degrees Celsius (° C.).

For example, they are materials such as fluorinated elastomers (of the FKM type) or a mixture of synthetic rubber, elastomer and a fluorinated polymer material.

These materials are particularly beneficial for forming the second seal because they are resistant to high temperatures (typically up to 200° C.) and to gases such as ozone and oxygen or plasma.

Furthermore, these materials have a low permeability to gases, and especially those used to passivate the photovoltaic cell described hereafter.

In other words, the materials used to form the second seal 25 are particularly adapted to the implementation of the passivation of photovoltaic cells because they will not be damaged during this implementation. By virtue of the properties of the material used to form it, the sealing qualities of the second seal 25 are preserved for the applications aimed at in the present invention (and in particular for the deposition of passivation layers).

The second seal 25 is, for example, a Viton™ brand fluoroelastomer static seal.

The second seal 25 is attached to the third support face 20A of the second support part 20. Whatever the attachment used, the second seal 25 is attached to the second support part 20 so as to be located facing the periphery of the photovoltaic cell 5. More particularly, the second seal 25 is attached to the second support part 20 so as to be located facing the end border of the second face 5B of the photovoltaic cell 5.

Thus, the second seal 25 is positioned, on the third support face 20A of the second support part 20, facing the first seal 15 attached to the first support part 10. This is particularly beneficial when holding the photovoltaic cell 5 between the first support part 10 and the second support part 20 because this positioning, in which the first seal 15 and the second seal 25 face each other, results in symmetrical bearing for the photovoltaic cell 5 (on the first face 5A and the second face 5B). This avoids any possible imbalance in the pressure forces applied to the two faces of the photovoltaic cell 5, and therefore avoids any risk of degradation or even breakage of the photovoltaic cell 5 when it is held in the holding device 1 (for deposition of passivation layer, for example).

Beneficially, the third support face 20 A of the second support part 20 comprises a groove 26 shaped to enable the second seal 25 to be attached in the second support part 20.

As is visible in FIGS. 2 and 3, the groove 26 is “dug” into the second support part 20 from the third support face 20A of the second support part 20.

Here, the groove 26 extends at the border of the second support part 20, over the entire periphery of the third support face 20A. This enables the second seal 25 to be positioned (and attached) facing the periphery of the second face 5B of the photovoltaic cell 5.

So as to enable the second seal 25 to be attached to the second support part 20, the groove 26, for example, has a smaller cross-sectional area (in the plane of the third support face 20A) at its opening (therefore at the third support face 20A) than at its bottom wall (in a plane parallel to the plane of the third support face 20A).

The second seal 25 is inserted into the groove 26 thus shaped by exerting a pressure force (that is, compressing it). The opening of the groove, which has a smaller cross-sectional area, then makes it possible to hold the second seal 25 in the groove 26, and thus to attach it to the second support part 20.

Alternatively, the groove 26 may have a smaller transverse cross-sectional area (that is, in a plane orthogonal to the third support face 20A) than the transverse cross-sectional area of the second seal 25.

The second seal 25 is inserted into the groove 26 shaped according to this alternative by exerting a pressure force (that is, compressing it). Once inserted into this groove 26, the second seal 25 relaxes. This relaxation then results in a pressure force being exerted by the second seal 25 on the walls of the groove 26. This then holds the second seal 25 in the groove 26 (and thus enables it to be attached to the third support part 20).

As an alternative to the groove described, the second seal 25 can be attached by bonding to the third support face 20A of the second support part 20. The glue used for bonding especially has properties of resistance to high temperatures (typically up to 200° C.). The glue also has low permeability to gases, and especially the gases used for passivation of the photovoltaic cell described hereafter. A fluoroelastomer-based glue can, for example, be used in this alternative.

Thus, the first support part 10 and the second support part 20 are arranged so as to “sandwich” the photovoltaic cell 5 to hold it in the holding device 1. More particularly, as visible in FIGS. 1 to 3, the photovoltaic cell 5 is positioned between the first seal 15 and the second seal 25.

Beneficially, as previously described, the first seal 15 and the second seal 25 are positioned facing each other so as to bear symmetrically, respectively, on the first face 5A and the second face 5B of the photovoltaic cell 5.

In order for the photovoltaic cell 5 to be held in the holding device 1 in a particular position (especially for the deposition of a passivation layer described hereafter), the holding device 1 comprises compression devices 30A, 30B; 30C.

These compression devices 30A, 30B; 30C are configured to hold the photovoltaic cell 5 bearing tightly against the first seal 15 and the second seal 25.

In this description, it is meant by “bearing tightly”, tightly holding the photovoltaic cell 5 between the first seal 15 and the second seal 25 by exerting some pressure on it.

In other words, the compression devices 30A, 30B; 30C enable the photovoltaic cell 5 to be held firmly between the first seal and the second seal 25 (thus between the first support part 10 and the second support part 20) so that the position of the photovoltaic cell 5 thus held cannot be altered.

In view of the shape and positioning of the first seal 15 and the second seal 25, the tight bearing is implemented at the periphery of the first face 5A and the second face 5B of the photovoltaic cell 5, symmetrically on the first face 5A and the second face 5B.

In other words, this tight bearing is carried out on those parts of the faces of the photovoltaic cell 5 that do not comprise metallisation or fragile elements. Localising this tight bearing therefore avoids degrading the photovoltaic cell 5 and its electrical performance.

In addition, this arrangement makes it possible to exert a holding pressure force at the same level on the first face 5A and the second face 5B of the photovoltaic cell 5, so that there is no imbalance between the forces exerted on the two faces of the photovoltaic cell 5. This then avoids the risk of breakage of the photovoltaic cell 5.

As is visible in FIGS. 1 to 3, when the photovoltaic cell 5 is held in the holding device 1, only the peripheral edge 5C of the photovoltaic cell 5 is visible and accessible from the outside of the holding device 1 (into which the photovoltaic cell 5 is inserted). In other words, the first seal 15 and the second seal 25 isolate the first face 5A and the second face 5B of the photovoltaic cell 5, placed in the holding device 1, from the outside of the holding device 1 (and in particular, as will be described hereinafter, from the passivation species used for depositing a passivation layer).

In practice, the compression devices 30A, 30B; 30C are configured to exert a pressure force greater than 2 Newtons (N).

According to an embodiment of the invention, the compression devices 30A, 30B; 30C are configured to exert a pressure force of between 2 and 10 N. Beneficially, this pressure force is sufficient to hold the photovoltaic cell 5 in position, without the photovoltaic cell 5 being able to move between the first seal 15 and the second seal 25 (and therefore between the first support part 10 and the second support part 20). Furthermore, the pressure force exerted by the compression device 30A, 30B; 30C are not too great to avoid the risks of breakage of the photovoltaic cell 5 (when it is held bearing tightly between the first seal 15 and the second seal 25).

In practice, two positions of the holding device 1 can be identified depending on the state of the compression devices 30A, 30B; 30C. When the compression devices 30A, 30B; 30C are in a state of rest (that is, they do not exert any compression force), the holding device is in a position known as the “loading position”, in which the photovoltaic cell 5 can be positioned between the first support part 10 and the second support part 20. The holding device 1 is, in a way, “open”. In other words, in this loading position, the first seal 15 and the second seal 25 are at a distance from each other, that is, a space is defined between the two.

In this first embodiment, the spacing between the first support part 10 and the second support part 20, in the loading position of the holding device 1, is not decisive.

When the compression devices 30A, 30B; 30C exert the corresponding pressure force to hold the photovoltaic cell 5 between the first seal 15 and the second seal 25, the holding device 1 is in a position known as the “compression position”. FIGS. 1 to 3 illustrate the holding device 1 in this compression position. The loading position is not represented for this first embodiment (but is in FIGS. 5, 7 and 9 for the other embodiments of the holding device 100; 150; 200 described hereafter).

In other words, the compression devices 30A, 30B; 30C are configured to compress the first support part 10 and the second support part 20 from a loading position (enabling the photovoltaic cell 5 to be inserted into the holding device 1) to a compression position (in which the photovoltaic cell 5 is held bearing tightly between the first seal 15 and the second seal 25).

According to a first alternative represented in FIG. 2, the compression devices 30A, 30B comprise two pistons 30A, 30B positioned on either side of the first support part 10 and the second support part 20.

More particularly, the first piston 30A is positioned in contact with the second support face 10B of the first support part 10. The first piston 30A then exerts a pressure force directed towards the photovoltaic cell 5 so that the first seal 15 bears tightly against the first face 5A of the photovoltaic cell 5.

In turn, the second piston 30B is positioned in contact with the fourth face 20B of the second support part 20. The second piston 30B then exerts a pressure force directed towards the photovoltaic cell 5 so that the second seal 25 bears tightly against the second face 5B of the photovoltaic cell 5. The pressure forces exerted by the two pistons 30A, 30B are opposite and similar in magnitude so as to enable the photovoltaic cell 5 to be held between the first seal 15 and the second seal 25.

According to a second alternative represented in FIG. 3, the compression device 30C comprises a load element 30C positioned on the second support part 20. This load element 30C is for example a mass positioned on the fourth support face 20B of the second support part 20 and whose weight corresponds to the pressure force exerted to hold the photovoltaic cell 5 between the first seal 15 and the second seal 25.

Alternatively, this load element is formed, for example, by stacking a plurality of support parts (whose weight corresponds to the pressure force exerted to hold the photovoltaic cell 5 between the first seal 15 and the second seal 25).

In order to refine the positioning of the photovoltaic cell 5 between the first support part 10 and the second support part 20 (more particularly between the first seal 15 and the second seal 25), so as to ensure that this positioning is accurate, the holding device 1 also comprises positioning system 40A, 40B, 40C, 40D for positioning the photovoltaic cell 5 between the first support part 10 and the second support part 20. These positioning systems 40A, 40B, 40C, 40D are configured to position the photovoltaic cell 5 between the first seal 15 and the second seal 25 so that the perimeter of the photovoltaic cell 5 faces the first seal 15 and the second seal 25.

In other words, the positioning systems 40A, 40B, 40C, 40D enable the photovoltaic cell 5 to be positioned, in the holding device 1, between the first support part 10 and the second support part 20 in order to align the perimeter of the photovoltaic cell 5 with the first seal 15 and the second seal 25. In other words, the peripheral edge 5C of the photovoltaic cell 5 extends in line with the first seal 15 and the second seal 25.

According to a first alternative embodiment represented in FIG. 4, the positioning systems 40A, 40B, 40C, 40D are formed by guide elements 40A, 40B, 40C, 40D. Four guide elements 40A, 40B, 40C, 40D are provided here, each guide element 40A, 40B, 40C, 40D being associated with one of the sides of the rectangular shape according to which the contour of the first peripheral seal 15 (or of the second peripheral seal 25) extends.

Each guide element 40A, 40B, 40C, 40D then comprises an end edge 41A, 41B, 41C, 41D intended to form a stop for one of the sides of the peripheral edge 5C of the photovoltaic cell 5.

In practice, each guide element 40A, 40B, 40C, 40D is positioned in such a way that the corresponding end edge 41A, 41B, 41C, 41D is positioned at the border of the first seal 15. In other words, each end edge 41A, 41B, 41C, 41D is positioned along the perimeter of the first seal 15. They then delimit a frame for receiving the photovoltaic cell 5 between the first support part 10 and the second support part 20. The reception frame thus delimited corresponds to the precise positioning required for the photovoltaic cell 5 to enable the perimeter of the photovoltaic cell 5 to be aligned with the first seal 15 and the second seal 25.

Alternatively, the guide elements could be formed as a single piece defining the aforementioned reception frame.

This first alternative embodiment corresponds to a manually-loaded holding device 1.

According to a second alternative embodiment (not represented), the positioning systems comprise a robotic arm configured to precisely position the photovoltaic cell 5 between the first support part 10 and the second support part 20. More particularly, the robotic arm is configured to position the photovoltaic cell 5 between the first seal 15 and the second seal 25 in order to align the perimeter of the photovoltaic cell 5 with the first seal 15 and the second seal 25. The robotic arm is therefore controlled to position the photovoltaic cell 5 in such a way that the peripheral edge 5C of the photovoltaic cell 5 extends in line with the first seal 15 and the second seal 25.

Conventionally, the robotic arm is connected to a controller and at least one sensor (not represented). The controller enables the robotic arm to be controlled so that the photovoltaic cell 5 is positioned precisely between the first seal 15 and the second seal 25 (and therefore between the first support part 10 and the second support part 20). For this purpose, the controller stores, for example, the position of the first support part 10 and the second support part 20 and controls the robotic arm so as to position the photovoltaic cell 5 in such a way that the perimeter of the photovoltaic cell 5 extends in the alignment of the first seal 15 and the second seal 25. The associated sensor(s) make(s) it possible to acquire information about the positioning, and to refine and check that it has been performed according to the command.

The use of the robotic arm corresponds to an alternative with automated loading of the holding device 1 in accordance with the invention.

Beneficially, the holding device 1 according to an embodiment of the invention ensures that only the peripheral edge 5C of the photovoltaic cell 5 is accessible from the outside of the holding device 1 when the photovoltaic cell 5 is held therein. This then ensures that only the peripheral edge 5C of the photovoltaic cell 5 can be exposed to the passivation species for the deposition of a passivation layer (the other parts of the photovoltaic cell 5 being isolated by virtue of the presence of the first seal 15 and the second seal 25 which form a barrier to the passivation species used).

It is to be noted that in practice a small surface of the front and rear faces (along the first seal and second seal) may also be exposed to passivation species for the deposition of the passivation layer. However, by virtue of the first seal and the second seal, the metallisations and the core of the photovoltaic cell (that is, the core of the front and rear faces) are effectively protected (that is, the deposition of the passivation layer does not reach these parts of the photovoltaic cell).

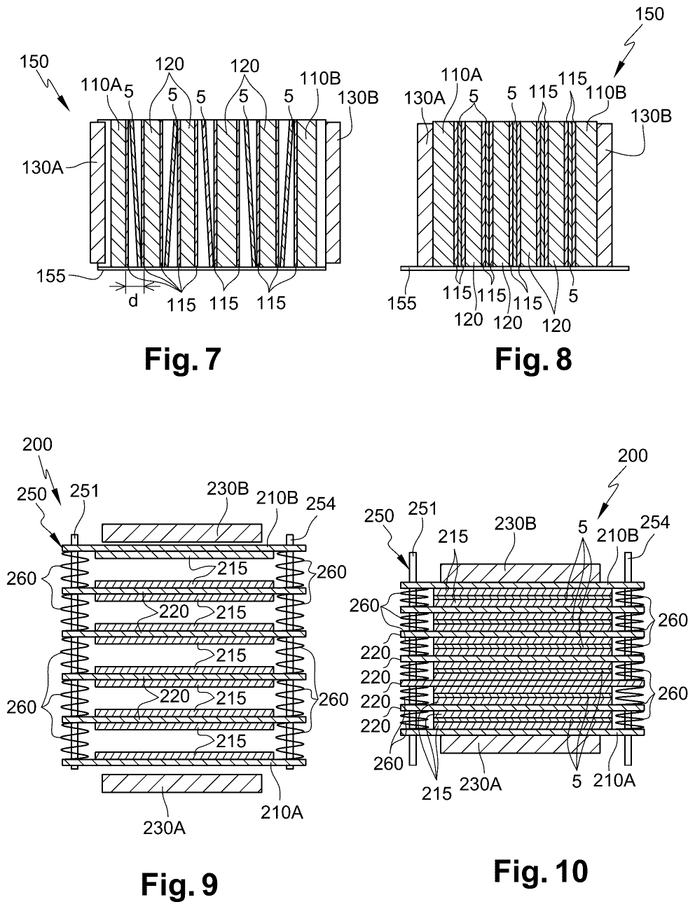

The first embodiment of the holding device 1 is represented in a vertical configuration in FIGS. 1 to 3. It is of course not limited to this vertical configuration and can, alternatively, be arranged according to a horizontal configuration (as represented for the third embodiment in FIGS. 7 and 8).

In such a horizontal configuration, it may be contemplated that the first support part and the second support part are held by vertical racks (acting as supports). The compression devices according to an embodiment of the invention are configured in such a way that in such a horizontal configuration, the photovoltaic cell does not slip between the first seal and the second seal. It is firmly held between the two.

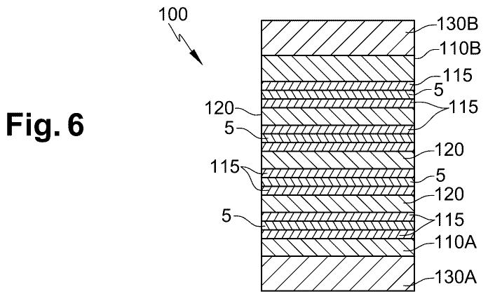

FIGS. 5 and 6 represent a second embodiment of the holding device 100 in accordance with the invention. FIG. 5 represents the holding device 100 according to this second embodiment in a loading position. FIG. 6 represents the holding device 100 according to this second embodiment in a compression position.

This holding device 100 according to this second embodiment is based on the same principle as that described according to the first embodiment. The difference lies in the fact that, in this second embodiment, the holding device 100 enables a plurality of photovoltaic cells 5 to be held. The photovoltaic cells 5 of this plurality all have the same overall shape and dimensions. The perimeter of these photovoltaic cells 5 is therefore substantially similar.

Only the differences between this second embodiment relative to the first embodiment are described in detail hereinafter.

As is visible in FIGS. 5 and 6, the holding device 100 comprises a plurality of support parts 110A, 110B, 120, a plurality of seals 115 and compression devices 130A, 130B.

Each seal 115 of the plurality of seals has the same characteristics as the first seal 15 and the second seal 25 described for the first embodiment. These characteristics are therefore not described again here.

The plurality of support parts 110A, 110B, 120 comprises end support parts 110A, 110B and intermediate support parts 120.

The two end support parts 110A, 110B respectively have the same characteristics as the first support part 10 and the second support part 20 described in the first embodiment of the holding device 1. They are therefore not described in detail again here. As is visible in FIGS. 5 and 6, these end support parts 110A, 110B are provided, only on one of their support faces 110C, 110D, with a seal 115.

In contrast, the intermediate support parts 120 are provided with two seals 115. Each intermediate support part 120 comprises, like the end support parts 110A, 110B, the first support part 10 and the second support part 20, two opposite support faces 120A, 120B.

As shown in FIGS. 5 and 6, each support face 120A, 120B is provided with a seal 115. In other words, each intermediate support part 120 is provided with two seals 115, one on each support face 120A, 120B. As in the first embodiment, each seal 115 is configured to bear against one of the faces 5A, 5B of the photovoltaic cell 5 concerned.

Finally, the intermediate support parts 120 have the same characteristics as the end support parts 110A, 110B, the first support part 10 and the second support part 20, except that they are provided, on their two support faces 120A, 120B, with a seal 115 configured to bear against one of the faces 5A, 5B of the photovoltaic cells 5.

In order for the plurality of photovoltaic cells 5 to be held in the holding device 100 in a particular position (especially for the deposition of a passivation layer described hereafter), the holding device 100 also comprises compression devices 130A, 130B.

These compression devices 130A, 130B are similar to those described in the first embodiment but adapted to the configuration of the second embodiment with a plurality of support parts 110A, 110B, 120 and a plurality of seals 115 and so as to hold a plurality of photovoltaic cells 5.

For example, in the case where the compression devices 130A, 130B comprise two pistons 130A, 130B, these two pistons 130A, 130B are positioned on either side of the two end support parts 110A, 110B.

More particularly, each of the pistons 130A, 130B is positioned in contact with the free (that is, with no seal) support face of the corresponding end support part 110A, 110B. The two pistons 130A, 130B then exert opposite pressure forces that are similar in magnitude so as to hold the photovoltaic cells 5 bearing tightly against the seals 115 concerned.

The holding device 100 according to this second embodiment also comprises positioning system (not represented in the figures). Here, too, these positioning systems are similar to those previously described for the first embodiment except that they are also adapted to the configuration of the second embodiment with a plurality of support parts 110A, 110B, 120 and a plurality of seals 115 and so as to hold a plurality of photovoltaic cells 5.

For example, a plurality of assemblies of guide elements may be provided, each assembly being associated with the positioning of one of the photovoltaic cells 5 of the plurality of photovoltaic cells 5 to be positioned.

FIGS. 7 and 8 represent a third embodiment of the holding device 150 in accordance with the invention. FIG. 7 represents the holding device 150 according to this third embodiment in a loading position. FIG. 8 represents the holding device 150 according to this third embodiment in a compression position.

This holding device 150 according to this third embodiment is based on the same principle as that described according to the second embodiment. The difference lies in the fact that, in this third embodiment, the holding device 150 is arranged according to a horizontal configuration.

The difference with the second embodiment previously described especially lies in the fact that, in the loading position (FIG. 7), the holding device 150 comprises a support 155 enabling the photovoltaic cells 5 to be held when they are loaded into the holding device 150.

This support 155 comprises, for example, a rail configured to abut against the support parts 110A, 110B, 120 so as to retain the photovoltaic cells 5 in the holding device 150 when they are loaded.

Alternatively, this support 155 may be formed by a part of the assembly of the guide elements. This part of the assembly of the guide elements is then positioned, for example, on the side of the holding device 150 from which the photovoltaic cells 5 inserted might fall. This part of the assembly of the guide elements then forms a stop for one of the sides of the peripheral edge 5C of each photovoltaic cell 5 inserted into the holding device 150.

For example, this support 155 is removable. For example, it can be movably mounted to the holding device 150 so that it can move between a position of use, when the photovoltaic cells 5 are loaded into the holding device 150, so as to form a stop for them, and a holding position in which the photovoltaic cells 5 are held bearing tightly between the seals 115. In this holding position, the support 155 is for example positioned at a distance from the support parts 110A, 110B, 120 (so as to no longer be in contact with them).

Whereas in the other embodiments described in this application, no spacing constraints are imposed between the support parts, the horizontal arrangement of this third embodiment requires an additional condition.

Indeed, in order to avoid tipping out of the photovoltaic cells when they are loaded (which could degrade them), the distance d between two adjacent support parts 110A, 110B, 120 is limited. This distance d is, for example, less than 10 times the thickness of the photovoltaic cells 5. In an embodiment, this distance d is less than 5 times the thickness of the photovoltaic cells 5.

FIGS. 9 and 10 represent a fourth embodiment of the holding device 200 in accordance with the invention. FIG. 9 represents the holding device 200 according to this fourth embodiment in a loading position. FIG. 10 represents the holding device 200 according to this fourth embodiment in a compression position.

This holding device 200 according to this fourth embodiment is based on the same principle as that described according to the second embodiment. The difference lies in the fact that, in this fourth embodiment, the compression devices 230A, 230B are coupled to a spring support system 250. This spring support system 250 is configured to dampen the compression movement and facilitate the return to the loading position when the compression devices 230A, 230B no longer exert the compression force on the plurality of support parts 210A, 210B, 220.

The spring support system 250 here comprises four uprights 251, 252, 253, 254 extending between the two end parts 210A, 210B. Here, the four uprights 251, 252, 253, 254 cooperate with the support parts 210A, 210B, 220.

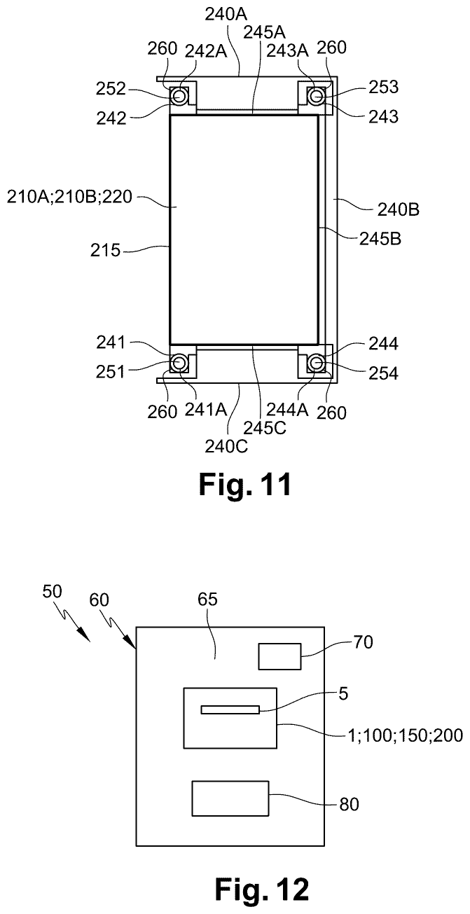

For this purpose, in this fourth embodiment, the support parts 210A, 210B, 220 have an extension part 241, 242, 243, 244 at their corners in order to cooperate with the spring support system 250 (FIG. 11).

More particularly here, as visible in FIG. 11, each support part 210A, 210B, 220 comprises, at each of its corners an expansion of material, the extension part 241, 242, 243, 244. Each extension part 241, 242, 243, 244 comprises an opening 241A, 242A, 243A, 244A, through which the corresponding upright 251, 252, 253, 254 extends.

As is visible in FIGS. 9 to 11, the spring support system also comprises a plurality of springs 260. More particularly, each upright 251, 252, 253, 254 is equipped with at least one spring 260.

Here, the spring support system 250 comprises a plurality of springs 260. Each spring 260 is positioned between two adjacent support parts 210A, 210B, 220. More particularly, as visible in FIG. 11, the ends of each spring 260 bear against the extension parts 241, 242, 243, 244. In practice, each of the ends of each spring bears on the extension parts 241, 242, 243, 244, on the periphery of the corresponding opening 241A, 242A, 243A, 244A.

Each spring 260 is a compression spring, with a stiffness of between 0.2 and 10 N/mm (Newton per millimetre).

Beneficially in this fourth embodiment, by virtue of this spring support system 250 (and the plurality of springs 260), each support part 210A, 210B, 220 slides along the uprights 251, 252, 253, 254, under the action of the plurality of springs 260. More particularly, each support part 210A, 210B, 220 slides along the uprights 251, 252, 253, 254 between the loading position and the compression position of the holding device 200. In the loading position, the plurality of springs 260 is in the rest position, the photovoltaic cells 5 can therefore be inserted between the support parts 210A, 210B, 220. In the compression position, the plurality of springs 260 is compressed, then enabling each photovoltaic cell 5 to be held bearing tightly between the two seals 215 concerned.

The holding device 200 according to this fourth embodiment also comprises positioning systems 240A, 240B, 240C.

As represented in FIG. 11, these positioning systems 240A, 240B, 240C are formed here, for example, by the guide elements 240A, 240B, 240C as previously described in the first embodiment (only three of the four guide elements are represented in FIG. 11).

The difference with the first embodiment lies in the shape of these guide elements 240A, 240B, 240C. Indeed here, they are shaped to take account of the extension parts 241, 242, 243, 244. As shown in FIG. 11, the guide elements 240A, 240B, 240C, 240D are here truncated at the extension parts 241, 242, 243, 244 so as to be complementary in shape thereto. This then guarantees that the end edge 245A, 245B, 245C can form a stop for one of the sides of the peripheral edge 5C of each photovoltaic cell 5 despite the presence of these extension parts 241, 242, 243, 244.

Thus, by virtue of their shape adapted to the configuration of this fourth embodiment (with the presence of uprights 251, 252, 253, 254 and extension parts 241, 242, 243, 244), each guide element 240A, 240B, 240C is positioned in such a way that the corresponding end edge 245A, 245B, 245C is positioned at the border of the seals 215. In other words, each end edge 245A, 245B, 245C is positioned along the perimeter of the seals 215, so as to delimit a reception frame for each photovoltaic cell 5 (each reception frame delimited thus corresponds to the precise positioning sought for the photovoltaic cell 5 to enable the perimeter of the photovoltaic cell 5 to be aligned with the seals 215 as previously described).

Whatever the embodiment of the holding device, the latter enables the photovoltaic cell or cells 5 to be held so that only the peripheral edge 5C of the photovoltaic cell 5 is accessible from the outside of the holding device when the photovoltaic cell 5 is held therein. This then ensures that only the peripheral edge 5C of the photovoltaic cells 5 is exposed to the passivation species for the deposition of the passivation layer (the other parts of the photovoltaic cells 5 being isolated by virtue of the presence of the seals which form a barrier to the passivation species used).

Furthermore, the elements forming the holding device have the characteristics necessary to withstand the passivation step. In other words, the different elements of the holding device especially have properties of resistance to high temperatures (typically up to 200° C.) and low permeability to the passivation species used for the passivation of the photovoltaic cell described hereafter.

An aspect of the invention also relates to a device 50 for depositing thin films onto at least one photovoltaic cell 5.

FIG. 12 represents an example of the thin film deposition device 50 in accordance with an embodiment of the present invention. This device 50 is used especially for depositing at least one passivation layer onto photovoltaic cells 5.

As shown in this figure, this thin film deposition device 50 comprises a thin film deposition enclosure 60, the holding device 1; 100; 150; 200 as previously described provided with at least one photovoltaic cell 5 and an injector 70 for injecting at least one passivation species.

The enclosure 60 for depositing thin films (and especially at least one passivation layer) comprises, for example, an assembly of walls for delimiting a housing 65 for accommodating the holding device 1; 100; 150; 200. This accommodation housing 65 is also that into which the passivation species are inserted so as to form passivation layers on the photovoltaic cells 5 (and especially on the peripheral edge 5C of each photovoltaic cell 5). This thin film deposition enclosure 60 is, for example, a vacuum deposition enclosure.

This thin film deposition enclosure 60 is dimensioned to accommodate the holding device 1; 100; 150; 250, as previously described, provided with one or more photovoltaic cells 5.

Furthermore, in order not to be damaged during the passivation process (that is, during the injection of passivation species so as to form the passivation layers), the inner walls of the thin film deposition enclosure 60 especially have properties of resistance to high temperatures (typically up to 200° C.) and low permeability to the passivation species used during this passivation process.

In order to enable formation of passivation layers on the photovoltaic cells 5, the thin film deposition device 50 comprises injector 70 for injecting at least one passivation species. In an embodiment, this passivation species is in the form of a gas.

In the present invention, a passivation layer is formed, for example, by Atomic Layer Deposition (ALD). According to this method, different precursor gases are inserted into the thin film deposition enclosure 60 and conveyed to the different zones (here the peripheral edge 5C of each photovoltaic cell 5) onto which one or more atomic layers are to be deposited.

In practice, an atomic layer is formed on a zone concerned (that is, here the peripheral edge 5C of each photovoltaic cell 5) by exposing this zone to the flow of a first precursor gas injected into the thin film deposition enclosure 60 by injector 70. This first precursor gas reacts with the terminations of the zone concerned and forms a monolayer containing other terminations (reactive groups). A second precursor gas (also injected by injector 70) is then inserted and reacts with the terminations of the monolayer formed (following injection of the first precursor gas) so as to form the desired passivation layer.

In practice, the injector 70 are formed, for example, by an injection head (not represented) enabling gas to be inserted into the thin film deposition enclosure 60. The deposition conditions (such as the position of the injection head, the flow rates of the gases, the concentration of the precursors and the temperature) and the dimensions of the injection head are beneficially chosen so that the passivation layer is formed at the peripheral edge 5C of each photovoltaic cell 5 held in the holding device 1; 100; 150; 200.

In an embodiment, the material of the passivation layer is, for example, alumina (Al₂O₃), silicon dioxide (SiO₂), silicon nitride (Si₃N₄) or hydrogenated amorphous silicon (a-Siₓ: H).

The thickness of the passivation layer is in the order of a few nanometres (nm) to a few tens of nanometres. For example, in the case of alumina, the thickness of the passivation layer is greater than 5 nm, for example between 5 and 15 nm. In the case of hydrogenated amorphous silicon nitride, the thickness of the passivation layer is in an embodiment between 5 and 15 nm.

Alternatively, the passivation species may be in the form of a vaporised liquid solution. For example, a vaporised liquid polymer solution can be used. The polymer here is a fluoropolymer such as Nafion™.

By virtue of the holding device 1; 100; 150; 200 previously described, only the peripheral edge 5C of each photovoltaic cell 5 held is exposed to the passivation species injected into the thin film deposition enclosure 60. Thus, beneficially, the passivation layer is formed only on the peripheral edge 5C of each photovoltaic cell 5 held in the holding device 1; 100; 150; 200 (when the passivation species injected into the thin film deposition enclosure 60 are flush with the peripheral edge 5C of each photovoltaic cell 5). Localising the deposition only on the peripheral edge (and not on all the faces of each photovoltaic cell) facilitates the subsequent step of interconnecting the photovoltaic cells. This avoids degrading the electrical performance of the photovoltaic cells.

Alternatively, the passivation layer can be deposited by other methods. For example, Physical Vapor Deposition (PVD) or Chemical Vapor deposition (CVD) methods can be used.

Still alternatively, a chemical liquid deposition method can be used.

Still alternatively, plasma-based deposition methods can also be used. In this case, the materials used, in particular for the support parts, have to be adapted to be conductive. For this, graphite can especially be used.

Beneficially, in order to define a directional flow around the holding device 1; 100; 150; 200 in the housing 65 for accommodating the thin film deposition enclosure 60, the latter also comprises a pumping system 80.

This pumping system 80 is configured to enable circulation of passivation species, around the holding device 1; 100; 150; 200, along a directional flow. The directional flow is defined here from one end of the holding device 1; 100; 150; 200 to the other. For example, the passivation species are circulated in the thin film deposition enclosure 60 from one of the end support parts to the other.

The directional flow is therefore imposed, in the thin film deposition enclosure 60, between the insertion of the passivation species, by the injector 70, and the suction generated by the pumping system 80. This makes it possible especially to ensure similar exposure to the passivation species for all the photovoltaic cells 5, on their entire peripheral edge 5C.

### Method for Holding at Least One Photovoltaic Cell

An aspect of the invention also relates to a method for holding at least one photovoltaic cell 5 in the holding device 1; 100; 150; 200 (in order then to deposit a passivation layer onto this photovoltaic cell 5).

The holding method firstly comprises a step of providing at least two support parts. These are, for example, the first support part 10 and the second support part 20 previously described. These support parts are provided with seals shaped as previously described.

The holding method then comprises a step of positioning the photovoltaic cell 5 between the two support parts, and more particularly between the two respective seals formed on the two support parts concerned.

Optionally, this positioning step may comprise a sub-step of adjusting the position of the photovoltaic cell 5 so as to ensure precise positioning. This sub-step is implemented by the positioning system previously described.

Finally, the holding method comprises a step of compressing a stack formed by the two support parts between which the photovoltaic cell 5 is positioned so as to hold the photovoltaic cell 5 bearing tightly against the two respective seals.

In the case of automated implementation of the holding method, the positioning step comprises positioning the first support part, then the photovoltaic cell (on the first seal of the first support part positioned), then the second support part (with the second seal in contact with the photovoltaic cell). In this case, this positioning is carried out by a robotic arm, for example, which successively positions each of the first support part, the photovoltaic cell and the second support part.

### Method for Passivating at Least One Photovoltaic Cell

Finally, an aspect of this invention relates to a method for passivating at least one photovoltaic cell 5.

Generally speaking, this passivation method comprises the following steps of:
holding the photovoltaic cell 5 in the holding device 1; 100; 150; 200 according to the holding method,
positioning the holding device 1; 100; 150; 200 provided with the photovoltaic cell 5 in the housing 65 for accommodating the thin film deposition enclosure 60,
injecting at least one passivation species into the thin film deposition enclosure 60 so as to form the passivation layer on the peripheral edge 5C of the photovoltaic cell 5 when the passivation species injected is flush with this peripheral edge 5C.

By virtue of the holding device 1; 100; 150; 200 as previously described, when the photovoltaic cell 5 is held in the holding device, only the peripheral edge 5C of the photovoltaic cell 5 is visible and accessible from the outside of the holding device 1 (into which the photovoltaic cell 5 is inserted). In other words, the first seal 15 and the second seal 25 isolate the first face 5A and the second face 5B of the photovoltaic cell 5, placed in the holding device, from the outside of the holding device. Thus, when the passivation species are injected from the thin film deposition enclosure 60, the passivation layer is formed only on the peripheral edge 5C of the photovoltaic cell 5 (when the passivation species injected is flush with this peripheral edge 5C and reacts with this peripheral edge).

The present invention is described for sub-cells but can also be implemented with full-size photovoltaic cells. In particular, for advanced cell technologies such as heterojunction (HET) cells, it may be useful to improve the existing passivation of the cell edges by forming a new passivation layer.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The present invention has been described and illustrated in the present detailed description and in the figures of the appended drawings, in possible embodiments. The present invention is not however limited to the embodiments described. Other alternatives and embodiments may be deduced and implemented by those skilled in the art on reading the present description and the appended drawings.

In the claims, the term “includes” or “comprises” does not exclude other elements or other steps. The different characteristics described and/or claimed may be beneficially combined. Their presence in the description or in the different dependent claims do not exclude this possibility. The reference signs cannot be understood as limiting the scope of the invention.

1. A device for holding at least one photovoltaic cell in order to form a passivation layer on a part of said photovoltaic cell, the photovoltaic cell comprising a first face, a second face, opposite to said first face, and a peripheral edge connecting the first face and the second face, the holding device comprising:
a first support part comprising a first support face and a second support face opposite to said first support face, the first support face being provided with a first seal shaped according to a perimeter of the photovoltaic cell,
a second support part comprising a third support face and a fourth support face opposite to said third support face, the third support face being provided with a second seal shaped according to the perimeter of the photovoltaic cell, and
a compression device configured to hold the photovoltaic cell bearing tightly against the first seal and against the second seal.

2. The holding device according to claim 1, further comprising a positioning system configured to position the photovoltaic cell between the first support part and the second support part.

3. The holding device according to claim 2, wherein the positioning system comprises guide elements positioned at the border of the first seal and/or of the second seal so as to position the perimeter of the photovoltaic cell facing the first seal and the second seal.

4. The holding device according to claim 2, wherein the positioning system comprises at least one robotic arm configured to position the photovoltaic cell between the first support part and the second support part so that the perimeter of the photovoltaic cell is positioned facing the first seal and the second seal.

5. The holding device according to claim 1, wherein the first support face of the first support part comprises a groove shaped to attach the first seal to the first support part.

6. The holding device according to claim 1, wherein the third support face of the second support part comprises a groove shaped to attach the second seal to the second support part.

7. The holding device according to claim 1, wherein the compression device is configured to exert a pressure force greater than 2 Newtons to hold the photovoltaic cell bearing tightly against the first seal and against the second seal.

8. The holding device according to claim 7, wherein the pressure force is between 2 and 10 Newtons.

9. The holding device according to claim 1, wherein the compression device comprises two pistons positioned on either side of the first support part and the second support part.

10. The holding device according to claim 7, wherein the compression device comprises a load element positioned on the second support part so as to exert said pressure force.

11. The holding device according to claim 1, wherein the first seal and the second seal are formed from a flexible polymer material.

12. The holding device according to claim 1, further comprising:
a third support part comprising a fifth support face and a sixth support face opposite to said fifth support face, the fifth support face being provided with a third seal shaped according to another perimeter of another photovoltaic cell, said other perimeter of the other photovoltaic cell being similar to the perimeter of the photovoltaic cell, said other photovoltaic cell comprising another first face, another second face, opposite to said other first face, and another peripheral edge connecting the other first face and the other second face,
the fourth support face of the second support part being provided with a fourth seal shaped according to the perimeter of the other photovoltaic cell, the compression device being configured to hold the other photovoltaic cell bearing tightly against the third seal and against the fourth seal.

13. A device for depositing thin films, and especially a passivation layer, onto at least part of a photovoltaic cell comprising:
a holding device according to claim 1,
at least one photovoltaic cell positioned in the holding device,
a thin film deposition enclosure comprising a side wall delimiting a housing for accommodating the holding device in which said photovoltaic cell is positioned, and
an injector configured to inject at least one passivation species making it possible to form a passivation layer on the peripheral edge of the photovoltaic cell when the passivation species is flush with the peripheral edge of the photovoltaic cell.

14. The thin film deposition device according to claim 13, further comprising a pumping device configured to pump the passivation species configured to enable circulation of the passivation species around the holding device along a directional flow.

15. A method for holding at least one photovoltaic cell comprising a first face, a second face opposite to said first face, and a peripheral edge connecting the first face and the second face, the method comprising:
providing a first support part comprising a first support face and a second support face opposite to said first support face, the first support face being provided with a first seal shaped according to a perimeter of the photovoltaic cell,
providing a second support part comprising a third support face and a fourth support face opposite to said third support face, the third support face being provided with a second seal shaped according to the perimeter of the photovoltaic cell,
positioning the photovoltaic cell between the first support part and the second support part, and
compressing a stack formed by the first support part, the photovoltaic cell and the second support part so as to hold the photovoltaic cell bearing tightly against the first seal and against the second seal.

16. The holding method according to claim 14, wherein the positioning comprises successively positioning the first support part, the photovoltaic cell and the second support part.

17. A method for passivating at least one photovoltaic cell, comprising:
holding the photovoltaic cell in a holding device according to a holding method according to claim 15,
positioning the holding device provided with the photovoltaic cell in a thin film deposition enclosure, and
injecting at least one passivation species into the thin film deposition enclosure so as to form a passivation layer on a peripheral edge of the photovoltaic cell when the passivation species is flush with the peripheral edge of the photovoltaic cell.
